(19) United States
(12) Patent Application Publication
(10) Pub. No.: US 2010/0194447 A1
(43) Pub. Date: Aug. 5, 2010

(54) ZERO INPUT BIAS CURRENT, AUTO-ZEROED BUFFER FOR A SAMPLE AND HOLD CIRCUIT

(76) Inventor: James Garrett, Nashua, NH (US)

Correspondence Address: CESARI AND MCKENNA, LLP, 88 BLACK FALCON AVENUE, BOSTON, MA, 02210, US

(21) Appl. No.: 12/365,960

(22) Filed: Feb. 5, 2009

(51) Int. Cl. H03K 3/00

(52) U.S. Cl. 327/108

(57) ABSTRACT

An auto-zeroing, high impedance buffer for a sample and hold module that draws substantially no current from the input and has substantially no offset voltage at the output is discussed. During a hold mode, the offset voltage of an op-amp is accumulated on a capacitor. When the sample operation ensues the input signal is directed to the op-amp input via the capacitor where the circuitry is arranged so that the offset on the capacitor cancels the offset voltage of the op-amp. A second circuit may be fashioned and input to a sample and hold circuit for full differential operation.

### BACKGROUND OF THE INVENTION

1. Field of the Invention

The present application relates to buffer circuits that may be placed before sample and hold circuits.

2. Background Information

Buffers operating with sample and hold circuits sometimes include a zeroing function that may be automatic. The auto-zeroing removes DC offsets that appear with the signal of interest. In some prior art zeroing approaches, the input signal may be tied to the sampling capacitor and draw current from it. In some applications where current is sensed, drawing current from the sampling capacitor may introduce unacceptable errors.

Auto-zeroing is especially useful where an op-amp (operational amplifier) may be part of the buffer and has an offset voltage that may substantially affect the signal of interest. Offset voltages in op-amps may be of any polarity and are typically amplified along with the input signal if the op-amp circuit is arranged with a gain.

Eliminating or zeroing offset voltages advantageously allows the circuit to operate without any adverse effects from an offset voltage changing, e.g., with temperature or common mode voltages.

### SUMMARY OF THE INVENTION

The present invention buffer includes an input op-amp that may be placed between the input signal and a sample and hold module. The op-amp presents a high impedance to the input signal and does not draw appreciable current from the input. An additional amplifier may be used between the input and the op-amp. The op-amp includes an inherent offset voltage that is zeroed out so that the input signal alone is presented to the sample and hold module. The present invention accommodates virtually any generic sample and hold module.

Typically a sample and hold circuit includes a two stage process that first samples an input signal and then holds that signal for processing. For example, an ADC (analog to digital converter) may use the holding time to convert the held analog signal into a digital value. After the hold and conversion, the input signal is sampled again.

Illustratively, when the sample and hold module is holding the input signal, the buffer may be auto-zeroing the input signal to remove the buffer's op-amp offset voltage. A capacitor is configured to accumulate only the offset voltage of the buffer, and hold that offset voltage for the sample operation. Then, when the sample and hold module is sampling the input signal, the buffer circuit is configured to incorporate the offset voltage held on the capacitor to cancel the offset voltage of the op-amp. In this manner, the buffer's op-amp output only contains the input signal free of any offset voltage.

Advantageously, the auto-zeroing buffer removes the offset voltage without loading the input signal, and the input signal does not connect to the sampling capacitor in the sample and hold module, where it may draw current adulterating the signal. Thus the present invention provides a buffer output signal with substantially no offset associated with the buffer while also drawing substantially no input bias current.

It will be appreciated by those skilled in the art that although the following Detailed Description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

The invention description below refers to the accompanying drawings, of which:

FIG. 1 is a schematic of a differential embodiment of the present invention;

FIG. 2 is a timing diagram illustrating the operation of an embodiment of the present invention; and

FIG. 3A and 3B are schematics and equations illustrating the handling of the offset voltage.

### DETAILED DESCRIPTION OF AN ILLUSTRATIVE EMBODIMENT

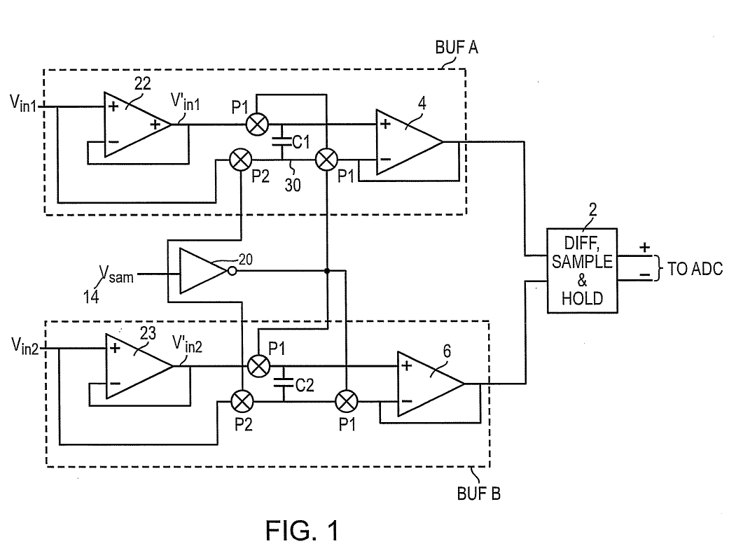

FIG. 1 is a full differential circuit embodiment of the present invention. Note that the present invention applies to a single ended configuration, for example only the BUFA and a single input sample and hold module (not shown). The sample and hold module 2 has a differential input with one input from BUFA and the other from BUFB. BUFA and BUFB are identical circuits buffering Vin1 and Vin2, respectively.

FIG. 1 includes unity gain amplifiers 22 and 23 with Vin1 and Vin2 connected to their inputs, respectively, and these unity gain amplifiers output V′in1 and V′in2, as shown. These unity gain amplifiers should exhibit offset voltages of 50 mV or less to keep input bias currents small.

As evident from FIG. 1 Vin1 and Vin2 provide common information to the difference amplifiers 4 and 6, respectively, where reasonable offsets of the amplifiers 4 and 6 are compensated.

P1 and P2 are switches, typically MOSFET transistors, that couple Vin1 and Vin2 to the capacitor C and to the op-amps 4 and 6, respectively. Herein “coupling” and “connecting” may be used interchangeably and both may include intervening components that do not appreciably affect the functions.

Vin1 is input to a unity gain amplifier 22 that output V′in1. V′in1 couples through a P1 switch to one side of C1 and to the + (non-inverting) input of the op-amp 4. Vin1 also couples through a P2 switch to the other side of C1 and then through a P1 switch to the − (inverting) input of op-amp 4. Vin2 connects similarly via unity gain amplifier 23 producing V′in2 and then through P1 and P2 switches to C2 and to the + and − inputs of op-amp 6.

The outputs of BUFA and BUFB are input to a differential sample and hold module 2 whose differential output, typically, will connect to an ADC (analog to digital converter) for converting the held signal into a digital number.

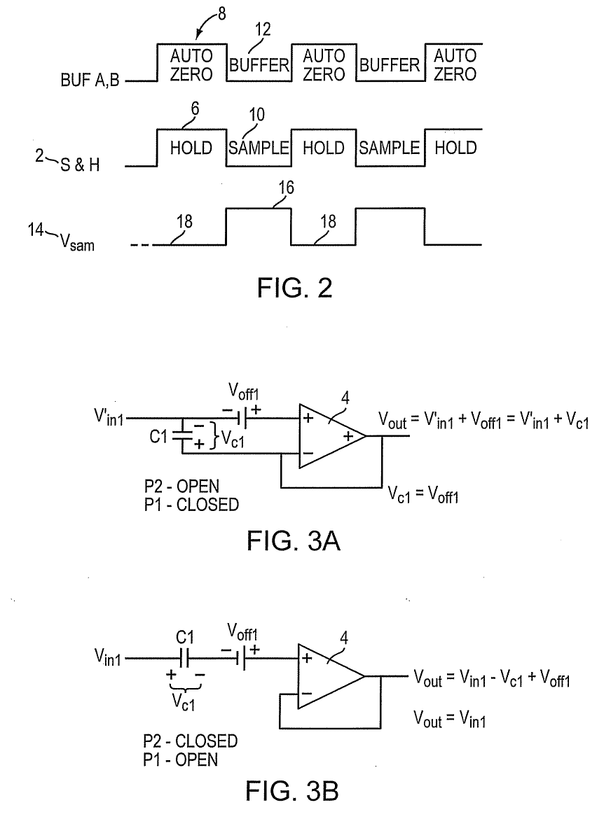

Referring to the timing diagrams of FIG. 2, when Vsam 18 is low, P1 switches are closed via inverter 20 and P2 switches are open. The BUFA and BUFB circuits are in the auto-zero mode 8 and the sample and hold module 2 is in the hold mode. The auto-zeroing operation of BUFA and BUFB are operating to remove the op-amp 4 and 6 offset voltages from the Vin1 and Vin2 signals to be presented to the sample and hold module 2 when Vsam goes high 16.

When Vsam is high, the P1 switches are open and the P2 switches are closed. The sample and hold module 2 is in the sample mode 10 and the BUFA and BUFB are in the buffer mode 12.

FIG. 3A illustrates the BUFA circuit with Vsam low, switches P1 are closed and P2 opened. The sample and hold module is in the HOLD 6 mode, and BUFA (and BUFB) is in the auto-zero mode. V′in1 is the output of a unity gain amplifier 22. C1 is a capacitor arranged bridging from the + input to the − inputs of the op-amp 4. Voff1 represents the offset voltage associated with op-amp 4. Note, the placing of Voff1 in + input of op-amp 4 is arbitrary for it may be placed in the inverting input, and the polarity may be reversed from that shown in FIG. 3A. Regardless of these facts, the analysis will be essentially the same as discussed below for the circuit in FIG. 3A.

In FIG. 3A, the voltage signal at the + input is V′in1 plus Voff1. The feedback connection operates so that the − input of op-amp 4 equals that of the + input. In this case the voltage at the − input of op-amp 4 is V′in1 plus Vc1, thus (V′in1+Voff1) equals (V′in1+Vc1), so Vc1=Voff1. The polarities are as shown in FIG. 3A.

FIG. 3B applies when the operation changes from auto-zero to buffer. Vsam goes high, switches P2 are closed and switches P1 are opened. Here Vin1 connects to point 30 (FIG. 1), the side of C1 that was just disconnected from the − input of op-amp 4. Note that the new conditions of the switches P1, P2 and P3 places the capacitor C1 such that the voltage Vc1 is reversed with respect to Voff1, and so these voltages cancel each other. Since Vc1 is reversed due to the switches, the voltage at the + input of op-amp 4 is Vin1−Vc1+Voff1. thus the output of op-amp 4 Vout is only Vin1.

Note that even though the Vin1 is connected to point 30, no charge is transferred from Vin1 to C1 since the other end of C1 only connects to the high impedance + input of op-amp 4 and therefore there is no current path.

The same analysis for BUFB circuit yields Vout of BUFB will be Vin2 at sample time 10.

Interestingly, the unity gain amplifier 22, that outputs V′in1 (similar for the unity gain amplifier 23 for Vin2) does not contribute its offset to the final output signal of the op-amp 4 when in the buffer 12 mode. V′in1 is used to accumulate the Voff1 across C1 during the auto-zero stage mode. But during the buffer 12 mode Vin1, not V′in1, is input to the op-amp + input via C1. Here the Voff1 across C1 cancels the actual Voff1, and Vin1 is output to the sample and hold module 2.

It should be understood that above-described embodiments are being presented herein as examples and that many variations and alternatives thereof are possible. Accordingly, the present invention should be viewed broadly as being defined only as set forth in the hereinafter appended claims.

What is claimed is:

1. A buffer defining an auto-zero mode and a buffer mode, the buffer comprising:
an op-amp that defines an out put signal, the op-amp having a non-inverting input and an inverting input;
a first switch having two terminals, one terminal coupled to an input signal and the other terminal coupled to the non-inverting input of the op-amp;
second and third switches, each having a first and a second terminal; wherein the first terminals are coupled to each other;
a capacitor coupled between the + input of the op-amp and the first terminals of the second and third switches;
the second terminal of the third switch is coupled to the inverting input of the op-amp, and the second terminal of the second switch is coupled to the input signal; wherein an auto-zero mode is defined when the first and the third switches are on and the second switch is off, and a buffer node is defined when the first and third switches are off and the second switch on in the buffer mode.

2. The buffer of claim 1 further defining an amplifier with an input and an output, the amplifier input connected to the input signal and the output coupled to the other terminal of the first switch.

3. The buffer of claim 1 wherein when in the auto-zero mode, the offset voltage of the op-amp is accumulated on the capacitor; and in the buffer mode, the offset voltage on the capacitor cancels the offset voltage of the op-amp, wherein the op-amp outputs the input signal free of any offset voltage.

4. The buffer of claim 1 wherein the first, second, third comprise MOSFET transistors, and wherein substantially no current is drawn from the inputs and the buffer defines an output with substantially no offset.

5. A method for buffering an input signal, the method comprising the steps of:
accumulating the offset voltage of an op-amp on a capacitor during an auto-zero mode;
during a buffer mode, switching the capacitor into the path of an input signal to the op-amp wherein the charge on the capacitor cancels the offset voltage of the op-amp.
wherein the output of the op-amp contains the input signal free of the offset voltage.

6. The method of claim 5 wherein substantially no current is drawn from the input signal and substantially no offset voltage appears at the output,

7. A method for buffering an input signal, the method comprising the steps of:
coupling the input signal to the non-inverting input of an op-amp via a switch;
coupling the op-amp output back to the inverting input of the op-amp;
coupling one side of a capacitor coupled to the + input of the op-amp and the other side of the capacitor to first terminals of a second and a third switches;
coupling the second terminal of the third switch to the inverting input of the op-amp, and coupling the second terminal of the second switch i to the input signal;
defining an auto-zero mode when the first and the third switches are on and the second switch is off, and
defining a buffer node when the first and third switches are off and the second switch on in the buffer mode.
